(19) United States
(12) Patent Application Publication
(10) Pub. No.: US 2026/0123354 A1
(43) Pub. Date: Apr. 30, 2026

(54) HEATER PEDESTAL WITH IMPROVED CHUCKING

(71) Applicant: Applied Materials, Inc., Santa Clara, CA (US)

(72) Inventors: Muhannad MUSTAFA, Milpitas, CA (US); Sanjeev BALUJA, Campbell, CA (US)

(21) Appl. No.: 18/932,437

(22) Filed: Oct. 30, 2024

(51) Int. Cl. H01L 21/683; H01L 21/67

(52) U.S. Cl. CPC H10P 72/78; H10P 72/0432

(57) ABSTRACT

A heater pedestal may include a heater plate. The heater plate may include a monolithic body and one or more heater elements disposed within the monolithic body. The monolithic body may include a first surface for supporting a substrate. The monolithic body may define: a first plurality of openings in the first surface; a second plurality of openings in a second surface of the monolithic body; and a plurality of channels, each respective channel of the plurality of channels extending from a respective opening of the first plurality of openings to a respective opening of the second plurality of openings. The heater pedestal may further include a post having a first surface coupled to the second surface of the monolithic body.

### BACKGROUND

### Field

Embodiments described herein generally relate to heater pedestals used in plasma processing systems. More particularly, embodiments described herein relate to a heater pedestal having a heater plate with a monolithic body for improved (e.g., more uniform) chucking.

### Description of the Related Art

Plasma processing systems utilize heater pedestals to support a substrate during processing (e.g., deposition) of the substrate. A heater pedestal may include one or more heater elements (e.g., heating coils). The heater element(s) may be operated to heat the substrate during processing to, for example, to achieve the desired chemical reactions, film properties, or material transformations. The heater pedestal may also include a plurality of vacuum chucking channels generally extend through the heater pedestal. The vacuum chucking channels may be used to create a vacuum between a support surface of the heater pedestal and a backside of a substrate supported by the support surface of the heater pedestal. Vacuum chucking channels on existing heater pedestals are typically located closer to the center of such heater pedestals than to a periphery (e.g, edge) of such heater pedestals and, as a result, the vacuum is stronger at the center of the substrate than at the edges of the substrate.

Accordingly, a need exists for heater pedestals having improved chucking.

### SUMMARY

In one aspect, a heater pedestal is provided. The heater pedestal includes a heater plate. The heater plate may include a monolithic body and one or more heater elements disposed within the monolithic body. The monolithic body may include a first surface for supporting a substrate. The monolithic body may define: a first plurality of openings in the first surface; a second plurality of openings in a second surface of the monolithic body; and a plurality of channels, each respective channel of the plurality of channels extending from a respective opening of the first plurality of openings to a respective opening of the second plurality of openings. The heater pedestal may further include a post having a first surface coupled to the second surface of the monolithic body.

In another aspect, a heater plate is provided. The heater plate includes: a monolithic body having a first surface for supporting a substrate; and one or more heater elements disposed within the monolithic body, wherein the monolithic body defines: a first plurality of openings in the first surface; a second plurality of openings in a second surface of the monolithic body; and a plurality of channels, each respective channel of the plurality of channels extending from a respective opening of the first plurality of openings to a respective opening of the second plurality of openings.

In yet another aspect, a method for forming a heater pedestal is provided. The method generally includes: forming a heater plate comprising a monolithic body having a first surface for supporting a substrate and a second surface for coupling the monolithic body to a post; forming a plurality of vacuum chucking channels in the monolithic body and forming a plurality of edge purge channels in the monolithic body, each of the plurality of vacuum chucking channels extending from the first surface to the second surface, each of the plurality of edge purge channels extending into the interior of the monolithic body from a third surface of the monolithic body; and subsequent to forming the plurality of vacuum chucking channels and the plurality of edge purge channels, coupling the monolithic body to the post.

### BRIEF DESCRIPTION OF THE DRAWINGS

So that the manner in which the above recited features of the disclosure can be understood in detail, a more particular description as described herein, briefly summarized above, may be had by reference to embodiments, some of which are illustrated in the appended drawings. It is to be noted, however, that the appended drawings illustrate only typical embodiments of this disclosure and are therefore not to be considered limiting of scope, for the disclosure may admit to other equally effective embodiments.

FIG. 1A depicts a heater pedestal according to some embodiments of the present disclosure.

FIG. 1B depicts components of the heater pedestal according to some embodiments of the present disclosure.

FIG. 2 depicts a block diagram of components of a heater pedestal according to some embodiments of the present disclosure.

FIG. 3A depicts a heater pedestal according to some embodiments of the present disclosure.

FIG. 3B depicts the heater pedestal with the heater pedestal decoupled from the post according to some embodiments of the present disclosure.

FIG. 3C depicts a perspective view of the heater pedestal according to some embodiments of the present disclosure.

FIG. 3D depicts a cross-sectional view of the heater pedestal illustrating vacuum chucking channels of the heater pedestal according to some embodiments of the present disclosure.

FIG. 3E depicts a bottom view of a portion of the heater pedestal according to some embodiments of the present disclosure.

FIG. 3F depicts another cross-sectional view of the heater pedestal to illustrate edge chucking channels of the heater pedestal according to some embodiments of the present disclosure.

FIG. 3G depicts a perspective view of the post of the heater pedestal according to some embodiments of the present disclosure.

FIG. 3H depicts a cross-sectional view of the post of the heater pedestal according to some embodiments of the present disclosure.

FIG. 4 depicts a flow diagram of an example method for forming a heater pedestal according to some embodiments of the present disclosure.

To facilitate understanding, identical reference numerals have been used, wherever possible, to designate identical elements that are common to the figures. It is contemplated that elements and/or process operations of one embodiment may be beneficially incorporated in other embodiments without additional recitation.

### DETAILED DESCRIPTION

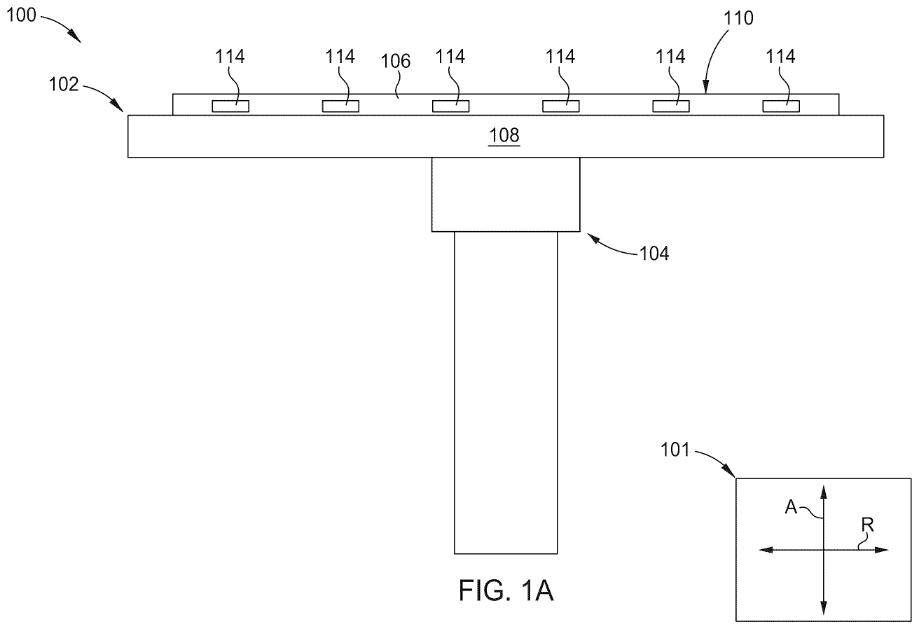

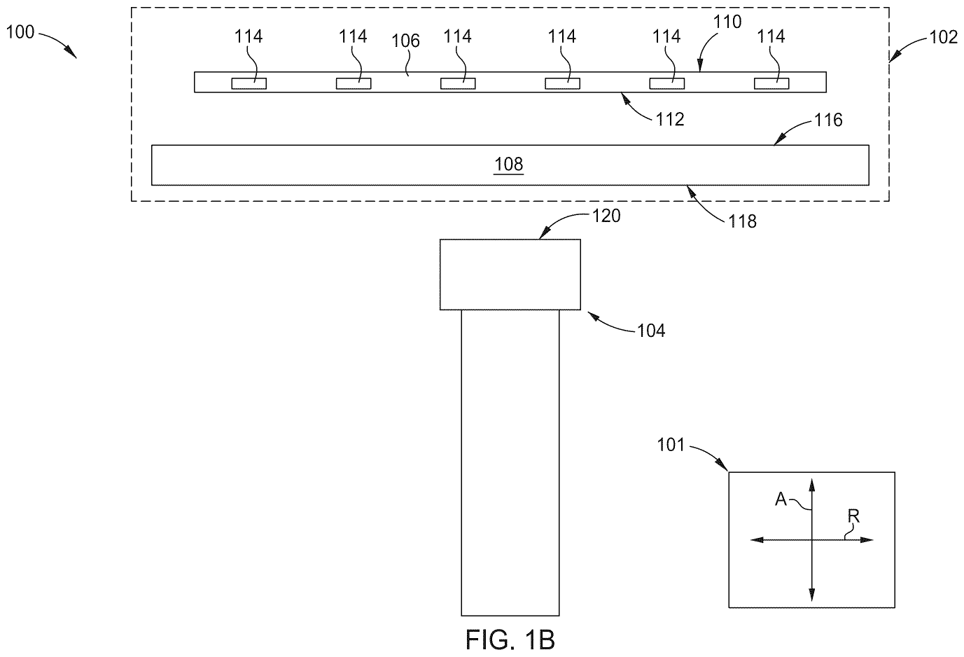

Example aspects of the present disclosure are directed to heater pedestals. As will be discussed with reference to FIGS. 1A and 1B, existing heater plates (e.g. formed from aluminum nitride) are typically formed by bonding a first plate including one or more heater elements with a second plate defining a plurality of channels (e.g., vacuum chucking channels and/or edge purge channels). Before bonding the first plate and the second plate to one another, a lapping processing is applied to a bonding surface on each plate to prepare (e.g., flatten and/or smooth) the bonding surface. The lapping process generally involves polishing the bonding surface with a metal tool (e.g., formed from copper). During the lapping process, a contaminant (e.g., the copper of the metal tool) may be applied to (e.g., rub off onto) the bonding surface and, after the two plates are diffusion bonded together and subsequently heated (e.g., in an oven), the contaminant may diffuse throughout the heater plate (that is, the first plate and second plate that are diffusion bonded to one another) and may contaminate a support surface of the heater pedestal. Furthermore, a substrate positioned on the contaminated support surface of the heater pedestal may be contaminated, which can negatively affect processing (e.g, deposition, etching, etc.) of the substrate.

Aspects of the present disclosure are directed to a heater pedestal with a heater plate that, instead of including two separate plates bonded (e.g., diffusion bonded) together, includes a monolithic body having a first surface for supporting the substrate and a second surface for coupling (e.g., diffusion bonding) the monolithic body to a post. The monolithic body also includes the heater element(s) and defines the plurality of channels (e.g., vacuum chucking channels, edge purge channels).

Example aspects of the present disclosure provide numerous technical effects and benefits. For instance, by forming the heater plate as a monolithic body, the above-mentioned diffusion bonding process implemented in existing heater pedestals is not needed. In this manner, the heater pedestal according to embodiments of the present disclosure avoids contaminating the support surface with a contaminant (e.g., copper) associated with the lapping process performed prior to diffusion bonding two surface to one another. Furthermore, the monolithic body allows for more varied placement of the vacuum chucking channels. For example, by forming the heater plate as a monolithic body instead of two separate plates diffusion bonded to one another, the vacuum chucking channels may be formed by drilling into the monolithic body such that the vacuum chucking channels extend through the monolithic body (e.g., from the first surface thereof to the second surface thereof) and are uniformly distributed across the first surface of the monolithic body. In this manner, a vacuum applied to a substrate supported by the heater plate according to some embodiments of the present disclosure may be improved (e.g., more uniform) compared to a vacuum applied to a substrate supported by existing heater plates.

Example of Heater Pedestal Including Heater Plate Formed from Two Separate Plates

FIGS. 1A and 1B depict a heater pedestal 100 according to some embodiments of the present disclosure. The heater pedestal 100 defines a coordinate system 101 including an axial direction A (e.g., top to bottom), a radial direction R (e.g., center to periphery), and a circumferential direction (not shown).

The heater plate assembly 102 includes a first plate 106 (e.g., top plate) and a second plate 108 (e.g., bottom plate). The first plate 106 extends (e.g., along the axial direction A) from a first surface 110 (e.g., top surface) for supporting a substrate to a second surface 112 (e.g., bottom surface). In some embodiments, the first plate 106 may define a plurality of channels 114 (e.g., associated with vacuum chucking and/or edge purging).

The second plate 108 extends (e.g., along the axial direction A) from a first surface 116 (e.g., top surface) to a second surface 118 (e.g. bottom surface). In some embodiments, the second plate 108 may include one or more heater elements (e.g., heating coils). The heater element(s) may be operable to heat a substrate (e.g., wafer) supported by the first surface 110 of the first plate 106.

The first plate 106 and the second plate 108 may be coupled to one another to form the heater plate assembly 102. More specifically, the first surface 116 of the second plate 108 may be bonded (e.g., diffusion bonded) to the second surface 112 of the first plate 106. In some embodiments, one or both of the surfaces (e.g., the first surface 116 of the second plate 108 and/or the second surface 112 of the first plate 106) involved may be subjected to a lapping process prior to being bonded to one another. For example, the lapping process may include using a metal tool (e.g., formed from copper) to polish and/or flatten the surfaces 112, 116 before being diffusion bonded to one another.

However, as a result of the lapping process, a contaminant (e.g., the copper included in the metal tool) may be applied to the surfaces 112, 116. Furthermore, after bonding (e.g., diffusion) the surfaces 112, 116 to one another and subsequently heating (e.g., in an oven) the heater plate assembly 102, the contaminant (e.g., copper from the metal tool) applied to the surfaces 112, 116 may diffuse and, in some instances, the contaminant may contaminate other portions of the heater plate assembly 102, such as the first surface 110 of the first plate 106 that supports the substrate (e.g., wafer). In such instances, the substrate itself may be contaminated, which may negatively affect processing of the substrate and/or performance of the substrate.

The post 104 of the heater pedestal 100 may be coupled to the heater plate assembly 102 of the heater pedestal 100. More specifically, a first surface 120 of the post 104 may be bonded (e.g., diffusion bonded) to the second surface 118 of the second plate 108 of the heater plate assembly 102. In some embodiments, one or both of the surfaces (e.g., the first surface 120 of the post 104 and/or the second surface 118 of the second plate 108) involved may be polished (e.g., using a metal tooling) prior to being bonded to one another.

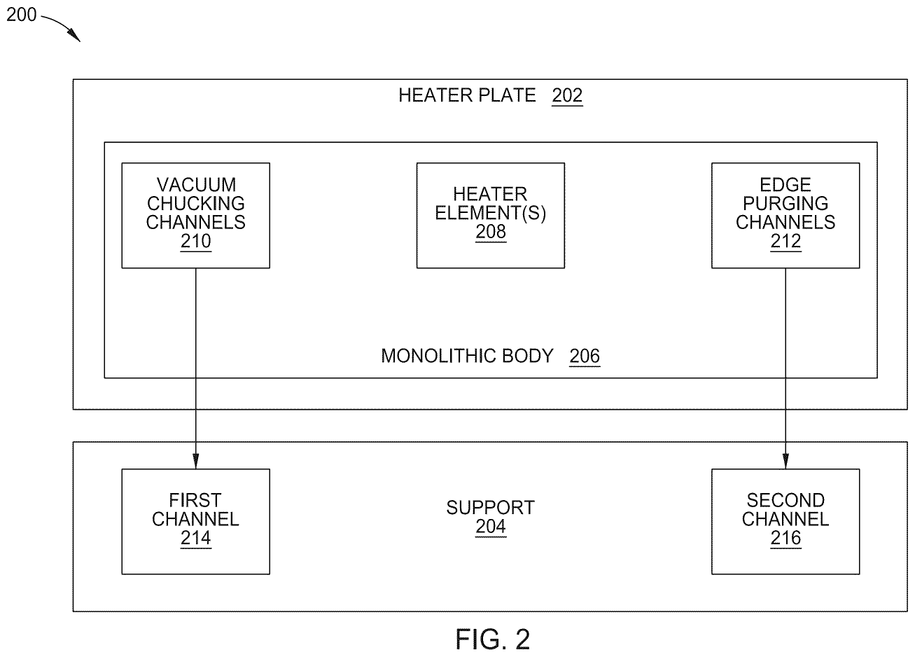

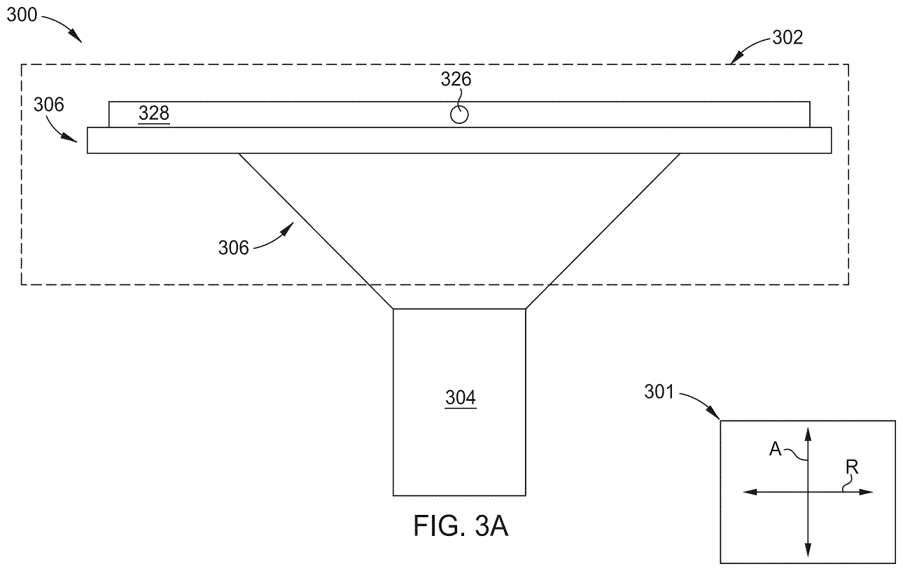

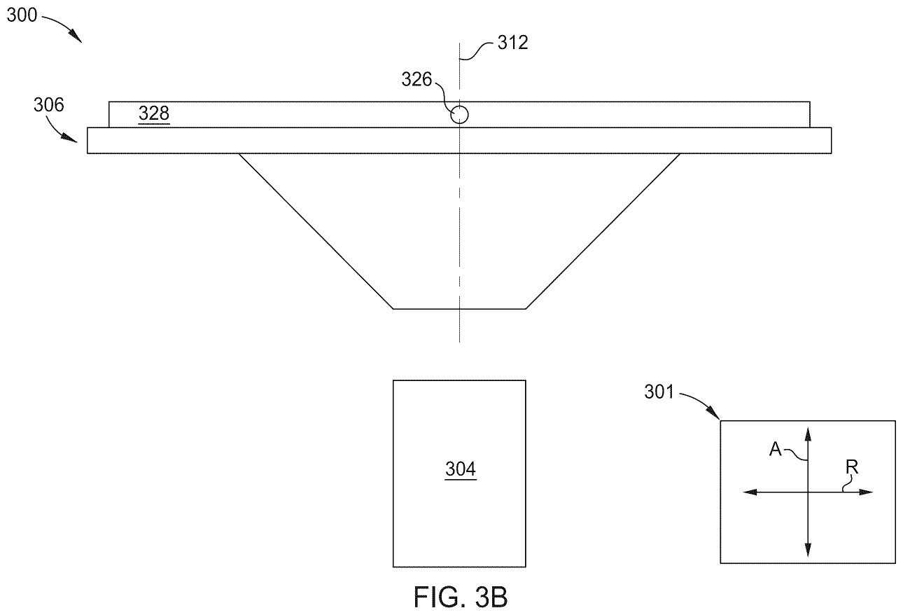

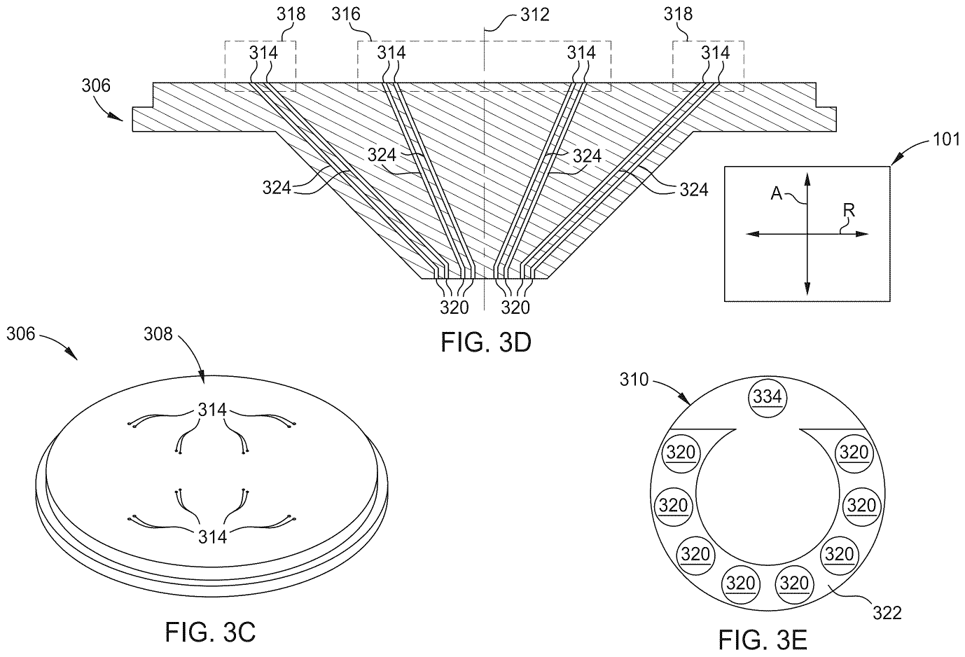

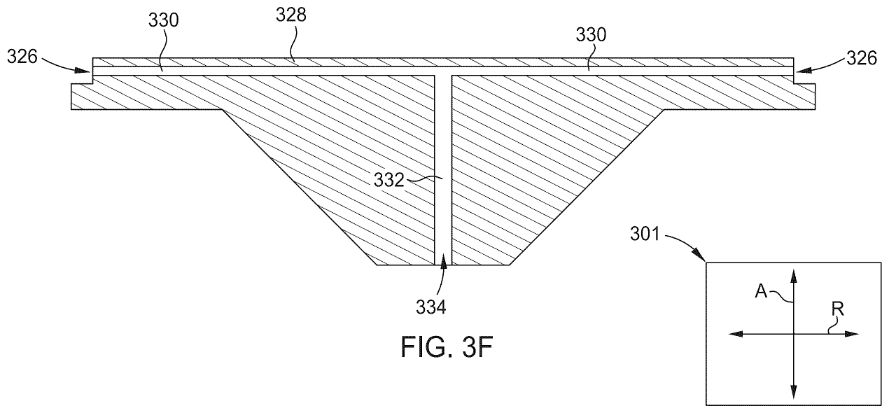

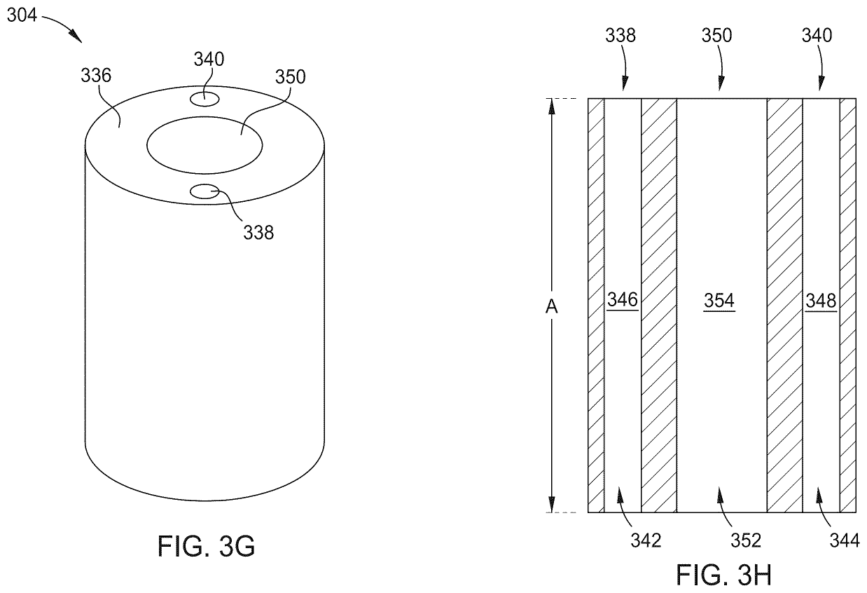

As will now be discussed with reference to FIG. 2 and FIGS. 3A-3H, example aspects of the present disclosure are directed to a heater pedestal that eliminates one of the diffusion bonds discussed above with reference to the heater pedestal of FIGS. 1A and 1B. More specifically, the heater pedestal according to some embodiments of the present disclosure includes a heater plate that, instead of having two separate plates (e.g., first plate 106 and second plate 108 of heater plate assembly 102 in FIGS. 1A and 1B), includes a single monolithic body. In this manner, the heater pedestal according to some embodiments of the present disclosure includes a heater plate that can be formed without diffusion bonding two plates to one another and, as a result, can generally avoid contaminating a substrate with a contaminant (e.g. one or more metals associated with the lapping process performed prior to diffusion bonding). Additionally, as will be discussed in more details in FIGS. 3A-3H, the monolithic body may allow vacuum chucking channels to be positioned uniformly across the heater pedestal resulting in improved (e.g., more uniform) vacuum chucking capability of the heater pedestal.

Example Heater Pedestal Having a Heater Plate with a Monolithic Body

FIG. 2 depicts a block diagram of components of a heater pedestal 200 according to some embodiments of the present disclosure. The heater pedestal 200 may include a heater plate 202 and a post 204. The heater plate 202 may be used to support and/or heat a substrate (e.g., wafer) during processing of the substrate.

The heater plate 202 may include a monolithic body 206. The monolithic body 206 may be a single plate as opposed to two plates diffusion bonded to one another like discussed above with reference to FIGS. 1A and 1B. The monolithic body 206 may include one or more heater elements 208 (e.g., heater coils) configured to heat a substrate supported by the monolithic body 206.

The monolithic body 206 may define a plurality of vacuum chucking channels 210 and a plurality of edge purging channels 212. For example, in some embodiments, the plurality of vacuum chucking channels 210 and the plurality of edge purging channels 212 may be formed in the monolithic body 206 by drilling (e.g., using a machine) into the monolithic body 206. In this manner, the vacuum chucking channels 210 and the edge purging channels 212 may be distributed uniformly on the monolithic body 206. For example, as will be discussed below with reference to FIG. 3C and FIG. 3D, the plurality of vacuum chucking channels 210 may include a first subset of channels positioned closer to a center (e.g., center line) of the monolithic body 206 than a periphery (e.g., edge) of the monolithic body 206. The plurality of vacuum chucking channels 210 may further include a second subset of channels positioned closer to the periphery of the monolithic body 206 than the center of the monolithic body 206.

The vacuum chucking channels 210 may allow a vacuum to be created between a substrate support surface of the monolithic body 206 and a backside of the substrate. The vacuum in essence “sucks” the substrate onto the monolithic body 206 during processing of the substrate. By securing the substrate to the monolithic body 206 via the vacuum, heat may transferred from the monolithic body, specifically the heater element(s) 208 thereof, to the substrate. In this manner, the monolithic body 206 may provide improved temperature control and uniformity during different processes (e.g., deposition, etching, annealing) associated with processing the substrate. Furthermore, in some embodiments, the vacuum chucking channels 210 may be used to supply a cooling gas (e.g., helium) to the backside of the substrate to help regulate the temperature of the substrate during high-power processes.

The edge purging channels 212 may allow the introduction of a purge gas (e.g., nitrogen, argon) around the edge (e.g., periphery) of the substrate. For example, the purge gas may help prevent deposition or etching of material on the edge of the substrate, which can lead to defects and contamination. The purge gas may also help maintain a consistent process in environment and gas flow dynamics across the substrate, which can improve uniformity of deposition, etching, or other processes performed on the substrate. In some embodiments, the purge gas may assist in clamping the substrate the monolithic body 206 by creating a pressure differential.

In some embodiments, the monolithic body 206 may be formed using a thermal process (e.g., sintering) in which a solid material (e.g., the monolithic body 206) is formed from material (e.g., metal or ceramic powder) by heating the material below its melting point. In alternative embodiments, the monolithic body 206 may be three-dimensional (3D) printed. Once the monolithic body 206 is formed (e.g., via sintering or 3D printed), the vacuum chucking channels 210 and edge purging channels 212 may be formed in the monolithic body 206. More specifically, the vacuum chucking channels 210 and the edge purge channels 212 may be drilled into the monolithic body 206. Furthermore, by forming the heater plate as the monolithic body 206 instead of two separate plates bonded to one another, the vacuum chucking channels 210 and the edge purge channels 212 may be distributed more uniformly. For example, the vacuum chucking channels 210 may be formed such that inlets for each of the vacuum chucking channels 210 are located uniformly along the support surface of the monolithic body 206.

The post 204 may define a first channels 214 and a second channel 216 that is separate from the first channel 214. Furthermore, the post 204 may be coupled to the heater plate 202, specifically the monolithic body 206 thereof, such that the first channel 214 defined by the post 204 is in fluid communication with each of the plurality of vacuum chucking channels 210 defined by the monolithic body 206 and the second channel 216 defined by the post 204 is in fluid communication with each of the plurality of edge purging channels 212 defined by the monolithic body 206.

In some embodiments, a surface of the post 204 may be bonded (e.g., diffusion bonded) to a surface (e.g., bottom surface) of the monolithic body 206. Furthermore, in such embodiments, the surface of the post 204 and the surface of the monolithic body 206 may be subjected to the same lapping process or a similar lapping process used to bond the heater plate assembly 102 and post 104 of the heater pedestal 100 discussed above with reference to FIGS. 1A and 1B.

FIGS. 3A-3H illustrate a heater pedestal 300 according to some embodiments of the present disclosure. In some embodiments, the heater pedestal 300 defines a coordinate system 301 including an axial direction A (e.g., top to bottom), a radial direction R (e.g., center to periphery), and a circumferential direction (not shown). In other embodiments, the heater pedestal 300 may define a different coordinate system, such as a coordinate system that includes a vertical direction, a lateral direction, and a longitudinal direction.

The heater plate 302 may include a monolithic body 306 similar to the monolithic body 206 discussed above with reference to FIG. 2. The monolithic body 306 may extend along the axial direction A from a first surface 308 of the monolithic body 306 to a second surface 310 of the monolithic body 306. The monolithic body 306 may also extend along the radial direction R from a center (e.g., center line 312) of the monolithic body 306 to a periphery (e.g., outermost edge) of the monolithic body 306.

The first surface 308 (e.g., support surface) of the monolithic body 306 may support a substrate (e.g., wafer) during processing of the substrate. Furthermore, as illustrated in FIGS. 3C and 3D, the first surface 308 of the monolithic body 306 may define a first plurality of openings 314. In some embodiments, the first plurality of openings 314 may include a first subset 316 of the openings 314 and a second subset 318 of the openings 314. As illustrated, each opening 314 included in the first subset 316 of the openings 314 may be positioned closer to the center (e.g., center line 312) of the monolithic body 306 than the periphery (e.g., outermost edge) of the monolithic body 306. In contrast, each opening 314 included in the second subset 318 of the openings 314 may be positioned closer to the periphery of the monolithic body 306 than the center of the monolithic body 306.

The second surface 310 of the monolithic body 306 may include a second plurality of openings 320. In some embodiments, the second surface 310 of the monolithic body 306 may define a channel 322 (e.g., groove) and the second plurality of openings 320 may be positioned within the channel 322.

The monolithic body 306 may define a plurality of channels 324 (e.g., vacuum chucking channels). As illustrated, each respective channel of the plurality of channels 324 may extend from a respective opening of the first plurality of openings 314 to a respective opening of the second plurality of openings 320. In this manner, each of the plurality of channels 324 may extend from the first surface 308 of the monolithic body 306 to the second surface 310 of the monolithic body 306.

The monolithic body 306 may include a third plurality of openings 326. For example, the third plurality of openings 326 may be defined in a third surface 328 of the monolithic body 306 and may be spaced apart from one another along the circumferential direction of the heater pedestal 300. Also, as illustrated, the third surface 328 of the monolithic body 306 may be oriented in a plane that is different (e.g., perpendicular) from a plane in which the first surface 308 of the monolithic body 306 and the second surface 310 of the monolithic body 306 are oriented.

The monolithic body 306 may include a plurality of horizontal channels 330 (e.g., only two illustrated for simplicity) extending along the radial direction R. More specifically, each respective horizontal channel of the plurality of horizontal channels 330 may extend inward (e.g., towards the center line 312 of the monolithic body 306) from a respective opening of the third plurality of openings 326.

The monolithic body 306 may define a vertical channel 332 in fluid communication with each of the plurality of horizontal channels 330. As illustrated, the vertical channel 332 may extend (e.g., along the axial direction A) to the second surface 310 of the monolithic body 306. More specifically, the vertical channel 332 may extend to a fourth opening 334 defined in the second surface 310 of the monolithic body 306. As illustrated in FIG. 3E, the fourth opening 334 may be positioned outside of the channel 322 defined in the second surface 310 of the monolithic body 306. In this manner, the fourth opening 334 that is in fluid communication with edge purging channels (e.g., collectively, the horizontal channels 330 and the vertical channel) may be isolated (e.g., not in fluid communication) from the second plurality of openings 320 that are in fluid communication with vacuum chucking channels (e.g., plurality of channels 324).

Since the heater plate 302 of the heater pedestal 300 includes the monolithic body 306 instead of two plates (e.g., first plate 106 and second plate 108 of heater plate assembly 102 discussed above with reference to FIGS. 1A and 1B, the openings 314 may be formed by drilling (e.g., using a machine) into the first surface 308 of the monolithic body 306. In this manner, the openings 314 may be more uniformly distributed along the first surface 308 of the monolithic body 306 with, as discussed above, the openings 314 including the first subset 316 positioned closer to the center (e.g., center line 312) of the monolithic body 306 and the second subset 318 positioned closer to the periphery of the monolithic body 306. In this manner, a vacuum created between the first surface 308 of the monolithic body 306 and a backside of a substrate positioned on the first surface 308 of the monolithic body 306 may be improved (e.g., more uniform) compared to conventional heater plates, such as the heater plate assembly 102 of FIGS. 1A and 1B, that include two separate plates bonded together (e.g., by diffusion bonding) and typically only include openings that are positioned closer to the center of the heater plate than the periphery of the heater plate.

Similar to the openings 314 formed in the first surface 308 of the monolithic body 306, the openings 326 formed in the third surface 328 of the monolithic body 306 may be more uniformly distributed (e.g., uniformly spaced along the circumferential direction) along the third surface 328 of the monolithic body 306. In this manner, uniformity control of the substrate that is accomplished using the edge purging channels (e.g., horizontal channels 330 and vertical channel 332) may be improved compared to heater plates that include two separate plates bonded together (e.g., by diffusion bonding) and typically include edge purging channels that are not uniformly distributed.

In some embodiments, the post 304 of the heater pedestal 300 may be coupled to the heater plate 302. For example, a first surface 336 of the post 304 may be bonded (e.g., diffusion bonded) to the second surface 310 of the monolithic body 306. Furthermore, in such embodiments, the surface of the post 304 and the surface of the monolithic body 206 may be subjected to the same lapping process or a similar lapping process used to bond the heater plate assembly 102 and post 104 of the heater pedestal 100 discussed above with reference to FIGS. 1A and 1B.

In some embodiments, a first opening 338 and a second opening 340 are defined in the first surface 336 of the post 304. Furthermore, a first opening 342 and a second opening 344 are defined in a second surface (e.g., bottom surface) of the post 304. As illustrated, the post 304 includes a first channel 346 extending (e.g., along the axial direction A) from the first opening 338 in the first surface 336 of the post 304 to the first opening 342 in the second surface of the post 304. The post 304 further includes a second channel 348 extending from the second opening 340 in the first surface 336 of the post 304 to the second opening 344 in the second surface of the post 304.

When the post 304 is coupled (e.g., diffusion bonded) to the monolithic body 306, the first channel 346 in the post 304 may be in fluid communication with the channel 322 in the second surface of the monolithic body 306. In this manner, the first channel 346 in the post 304 may be in fluid communication with the plurality of channels 324 (e.g., vacuum chucking channels). Also, the second channel 348 in the post 304 may be in fluid communication with the fourth opening 334 in the second surface 310 of the monolithic body 306. In this manner, the second channel 348 may be in fluid communication with the plurality of horizontal channels 330 (e.g., edge purging channels).

In some embodiments, a third opening 350 may be defined in the first surface 336 of the post 304 and a third opening 352 may be defined in the second surface of the post 304. Furthermore, a third channel 354 may extend (e.g, along the axial direction A) from the third opening 350 in the first surface 336 of the post 304 to the third opening 352 in the second surface of the post 304. In some embodiments, the third channel 354 may be used to route cabling (e.g., electrical cable) associated with the heater element(s) included in the monolithic body 306.

In some embodiments, a first portion of the monolithic body 306 may have a first shape and a second portion (e.g., positioned below the first portion along the axial direction A) of the monolithic body 306 may have a second shape that is different from the first shape. For example, in some embodiments, the first portion of the monolithic body 306 may have an annular shape and the second portion of the monolithic body 306 may have a frustoconical shape. It should be appreciated, however, that the scope of the present disclosure is not intended to be limited to a monolithic body like depicted in FIGS. 3A-3H and may therefore monolithic bodies having other shapes and used in heater pedestals.

### Example Operations for Forming a Heater Pedestal

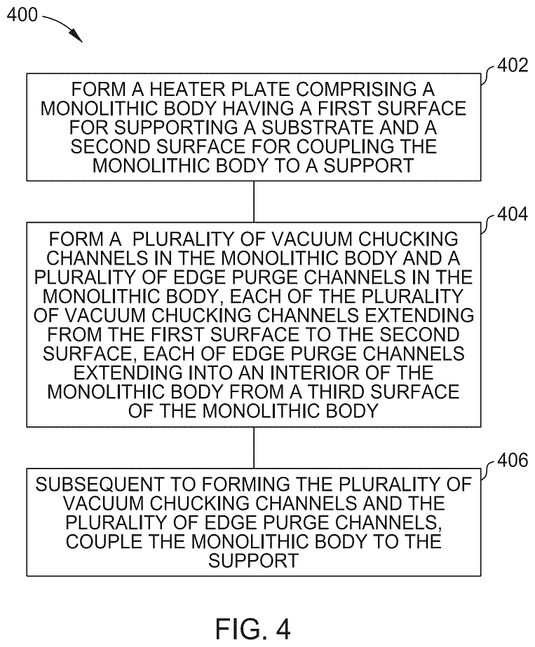

FIG. 4 is a diagram depicting a flow diagram of example operations 400 for forming a heater pedestal according to some embodiments of the present disclosure. For example, the method 900 may be used to form the heater pedestal discussed above with reference to FIGS. 3A-3H.

At (402), the operations 400 may include forming a heater plate, wherein forming the heater plate includes forming a monolithic body having a first surface (e.g., the first surface 308 of the monolithic body 306 of FIGS. 3A-3H) for supporting a substrate and a second surface (e.g., the second surface 310 of the monolithic body 306 of FIGS. 3A-3H) for coupling (e.g., bonding) the monolithic body to a post. It should be understood that forming the monolithic body does not include diffusion bonding two plates together like done to form heater plates for conventional heater pedestals, such as the heater plate assembly 102 of the heater plate assembly 102 discussed above with reference to FIGS. 1A and 1B. In this manner, the monolithic body formed at (402) is not contaminated with metals (e.g., copper associated with copper tools) that are used to prepare (e.g., by lapping) two surfaces for diffusion bonding.

At (404), the operations 400 may include forming a plurality of vacuum chucking channels (e.g., channels 324 in the monolithic body 306 of FIGS. 3A-3H) and a plurality of edge purge channels (e.g., horizontal channels 330 in the monolithic body 306 of FIGS. 3A-3H). For instance, in some embodiments, the plurality of vacuum chucking channels may be formed by drilling (e.g., using a machine) through the monolithic body, such as drilling from the first surface of the monolithic body to the second surface of the monolithic body. Additionally, the plurality of edge purge channels may be formed by drilling (e.g., using a machine) into the interior of the monolithic body from a third surface (e.g., third surface 328 of the monolithic body 306 of FIGS. 3A-3H).

Subsequent to forming the plurality of vacuum chucking channels and the plurality of edge purge channels, the operations 400 may, at (406), include coupling the monolithic body to the support (e.g., a shaft). In some embodiments, coupling the monolithic body to the support may include the second surface of the monolithic body and a first surface of the support to prepare (e.g., by flattening and/or smoothing) the surfaces for diffusion bonding and subsequently diffusion bonding the surfaces to one another to couple the monolithic body to the support.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A heater pedestal, comprising:
a heater plate comprising a monolithic body and one or more heater elements disposed within the monolithic body, the monolithic body having a first surface for supporting a substrate, the monolithic body defining:
a first plurality of openings in the first surface;
a second plurality of openings in a second surface of the monolithic body; and
a plurality of channels, each respective channel of the plurality of channels extending from a respective opening of the first plurality of openings to a respective opening of the second plurality of openings; and
a post having a first surface coupled to the second surface of the monolithic body.

2. The heater pedestal of claim 1, wherein the first surface of the post is diffusion bonded to the second surface of the monolithic body.

3. The heater pedestal of claim 1, wherein the post defines:
a first opening in the first surface of the post, the first opening of the post in fluid communication with each of the second plurality of openings of the monolithic body;
a second opening in a second surface of the post that is spaced apart from the first surface of the post along a longest axis of the post; and
a channel extending from the first opening of the post to the second opening.

4. The heater pedestal of claim 1, wherein:
the second surface of the monolithic body defines a groove; and
the second plurality of openings defined in the second surface of the monolithic body are positioned within the groove.

5. The heater pedestal of claim 1, wherein:
a first subset of the first plurality of openings is positioned closer to a center of the first surface than a periphery of the first surface; and
a second subset of the first plurality of openings is positioned closer to the periphery of the first surface than the center of the first surface.

6. The heater pedestal of claim 5, wherein the first subset and the second subset include a same number of openings.

7. The heater pedestal of claim 1, wherein the monolithic body further defines:
a third plurality of openings in a third surface of the monolithic body;
a fourth opening in the second surface of the monolithic body;
a plurality of horizontal channels, each respective channel of the plurality of horizontal channels extending from a respective opening of the third plurality of openings; and
a vertical channel in fluid communication with the fourth opening and each respective channel of the plurality of horizontal channels.

8. The heater pedestal of claim 7, wherein:
the first surface and the second surface are defined in a first plane; and
the third surface is defined in a second plane that is perpendicular to the first plane.

9. The heater pedestal of claim 7, wherein:
the second surface of the monolithic body defines a groove;
the second plurality of openings defined in the second surface of the monolithic body are positioned within the groove; and
the fourth opening defined in the second surface of the monolithic body is positioned outside of the groove.

10. The heater pedestal of claim 7, wherein the post defines:
a first opening in the first surface of the post, the first opening of the post in fluid communication with the fourth opening defined in the second surface of the monolithic body;
a second opening in a second surface of the post that is spaced apart from the first surface of the post along a longest axis of the post; and
a channel extending from the first opening of the post to the second opening.

11. A heater plate, comprising:
a monolithic body having a first surface for supporting a substrate; and
one or more heater elements disposed within the monolithic body,
wherein the monolithic body defines:
a first plurality of openings in the first surface;
a second plurality of openings in a second surface of the monolithic body; and
a plurality of channels, each respective channel of the plurality of channels extending from a respective opening of the first plurality of openings to a respective opening of the second plurality of openings.

12. The heater plate of claim 11, wherein
a first subset of the first plurality of openings is positioned closer to a center of the first surface than a periphery of the first surface; and
a second subset of the first plurality of openings is positioned closer to the periphery of the first surface than the center of the first surface.

13. The heater plate of claim 12, wherein the first subset and the second subset include a same number of openings.

14. The heater plate of claim 11, the second surface of the monolithic body defines a groove; and
the second plurality of openings defined in the second surface of the monolithic body are positioned within the groove.

15. The heater plate of claim 11, wherein the monolithic body further defines:
a third plurality of openings in a third surface of the monolithic body;
a fourth opening in the second surface of the monolithic body;
a plurality of horizontal channels, each respective channel of the plurality of horizontal channels extending from a respective opening of the third plurality of openings; and
a vertical channel in fluid communication with the fourth opening and each respective channel of the plurality of horizontal channels.

16. The heater plate of claim 15, wherein:
the second surface of the monolithic body defines a groove;
the second plurality of openings defined in the second surface of the monolithic body are positioned within the groove; and
the fourth opening defined in the second surface of the monolithic body is positioned outside of the groove.

17. The heater plate of claim 11, wherein:
the monolithic body comprises a first portion having a first shape and a second portion having a second shape that is different from the first shape;
the first portion of the monolithic body includes the first surface defining the first plurality of openings; and
the second portion of the monolithic body includes the second surface defining the second plurality of openings.

18. The heater plate of claim 17, wherein the second shape comprises a frustoconical shape.

19. A method for forming a heater pedestal, comprising:
forming a heater plate comprising a monolithic body having a first surface for supporting a substrate and a second surface for coupling the monolithic body to a post;
forming a plurality of vacuum chucking channels in the monolithic body and forming a plurality of edge purge channels in the monolithic body, each of the plurality of vacuum chucking channels extending from the first surface to the second surface, each of the plurality of edge purge channels extending into an interior of the monolithic body from a third surface of the monolithic body; and
subsequent to forming the plurality of vacuum chucking channels and the plurality of edge purge channels, coupling the monolithic body to the post.

20. The method of claim 19, wherein coupling the monolithic body to the post comprises:
lapping the second surface of the monolithic body and a first surface of the post; and
subsequent to the lapping, diffusion bonding the second surface of the monolithic body and the first surface of the post together to couple the monolithic body to the post.
